(19) United States
(12) Patent Application Publication
(10) Pub. No.: US 2026/0251702 A1
(43) Pub. Date: Aug. 27, 2026

(54) TEST CIRCUIT AND ELECTRO-OPTICAL DEVICE

(71) Applicant: SEIKO EPSON CORPORATION, Tokyo (JP)

(72) Inventors: Akira MORITA, CHINO-SHI (JP); Shinya UKAI, FUJIMI-MACHI (JP)

(73) Assignee: SEIKO EPSON CORPORATION, Tokyo (JP)

(21) Appl. No.: 19/550,325

(22) Filed: Feb. 26, 2026

(30) Foreign Application Priority Data
Feb. 27, 2025 (JP) 2025-029873

(51) Int. Cl. G01R 31/28; G02F 1/13

(52) U.S. Cl. CPC G01R 31/2884; G02F 1/1309

(57) ABSTRACT

A test circuit includes a first circuit including an amplifier having a first input node, a second input node, and an output node, a first switch coupled to the first input node, to which an initial potential is applied, and a second switch coupled to the second input node, to which a reference potential is applied, a second circuit including a first capacitive element provided between a test node and the first input node and coupled to the first input node, a third switch, a second capacitive element, and a fourth switch, and a control circuit controlling the first circuit and the second circuit, wherein a withstand voltage of the amplifier is lower than a voltage applied to the test node, and a capacitance of the second capacitive element is smaller than a capacitance of the first capacitive element.

The present application is based on, and claims priority from JP Application Serial Number 2025-029873, filed February 27, 2025, the disclosure of which is hereby incorporated by reference herein in its entirety.

### BACKGROUND

### 1. Technical Field

The present disclosure relates to a test circuit and an electro-optical device.

### 2. Related Art

JP-A-2022-137550 describes a measurement circuit of a driver circuit that outputs a data signal to a liquid crystal panel. The measurement circuit measures an amount of voltage change of the data signal output from the driver circuit. The measurement circuit includes a first capacitive element, a second capacitive element, a switch, a comparison circuit, and a control circuit. The voltage of the data signal to be measured is applied to one end of the first capacitive element, and the other end of the first capacitive element is electrically coupled to a comparison node of the comparison circuit.

To the comparison node of the comparison circuit, a first voltage is applied in a first period and a second voltage obtained by adding an amount of voltage divided according to a capacitance ratio between the first capacitive element and the second capacitive element to the amount of voltage change of the data signal is applied in a second period. Therefore, according to JP-A-2022-137550, a low-withstand-voltage transistor can be used in the comparison circuit.

JP-A-2022-137550 is an example of the related art.

In the measurement circuit described in JP-A-2022-137550, when the amount of voltage change of the data signal is large, there are problems that it is difficult to secure sufficient sensitivity in all of the magnitudes of the amount of voltage change, and it is difficult to perform highly accurate measurement.

### SUMMARY

A test circuit according to an aspect of the present application includes a first circuit including an amplifier having a first input node, a second input node, and an output node, a first switch having one end electrically coupled to the first input node and another end to which a first potential is applied, and a second switch having one end electrically coupled to the second input node and another end to which a second potential is applied, a second circuit including a first capacitive element provided between a test node and the first input node and having one end electrically coupled to the first input node, and a third switch having one end electrically coupled to another end of the first capacitive element and another end electrically coupled to the test node, a second capacitive element having one end electrically coupled to the first input node, and a fourth switch having one end electrically coupled to another end of the second capacitive element and another end electrically coupled to the test node, and a control circuit controlling the first circuit and the second circuit, wherein a withstand voltage of the amplifier is lower than a voltage applied to the test node, and a capacitance of the second capacitive element is smaller than a capacitance of the first capacitive element.

An electro-optical device according to an aspect of the present disclosure includes an electro-optical panel, a drive circuit that drives the electro-optical panel, and the above-described test circuit.

### BRIEF DESCRIPTION OF THE DRAWINGS

FIG. 1 is a perspective view showing an appearance of a driver including a test circuit according to an embodiment and an electro-optical device including the driver.

FIG. 2A is a block diagram showing a schematic configuration of the driver.

FIG. 2B is a block diagram showing a schematic configuration according to a modification of the driver.

FIG. 3 is a circuit diagram of the test circuit.

FIG. 4 is a timing chart showing an operation of the test circuit.

FIG. 5 is a circuit diagram of a test circuit according to Embodiment 2.

FIG. 6 is a timing chart showing an operation of the test circuit according to Embodiment 2.

FIG. 7 is a circuit diagram of a test circuit according to Embodiment 3.

FIG. 8A is a timing chart showing an operation of a test circuit of a comparative example of the test circuit of Embodiment 3.

FIG. 8B is a timing chart showing an operation of the test circuit according to Embodiment 3.

FIG. 9A is a circuit diagram of a test circuit according to Embodiment 4.

FIG. 9B is a circuit diagram of a test circuit according to a modification of Embodiment 4.

FIG. 10 is a timing chart showing an operation of the test circuit according to Embodiment 4.

FIG. 11 is a circuit diagram of a test circuit according to Embodiment 5.

FIG. 12A is a circuit diagram of a test circuit according to Embodiment 6.

FIG. 12B is a circuit diagram of a test circuit according to a modification of Embodiment 6.

FIG. 13A is a timing chart showing an operation of the test circuit according to Embodiment 6.

FIG. 13B is a timing chart showing the operation of the test circuit according to Embodiment 6.

FIG. 13C is a timing chart showing the operation of the test circuit according to Embodiment 6.

FIG. 14 is a circuit diagram of a test circuit according to Embodiment 7.

### DESCRIPTION OF EMBODIMENTS

### 1. Embodiment 1

### 1.1. Configuration of Electro-Optical Device 100

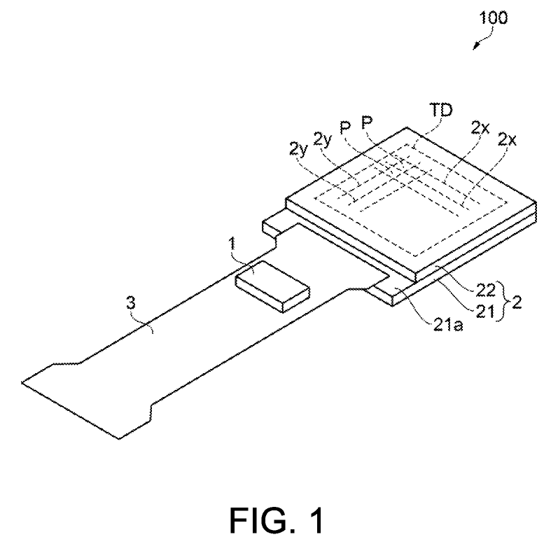

FIG. 1 is a perspective view showing an example of an appearance of an electro-optical device 100 according to the present embodiment.

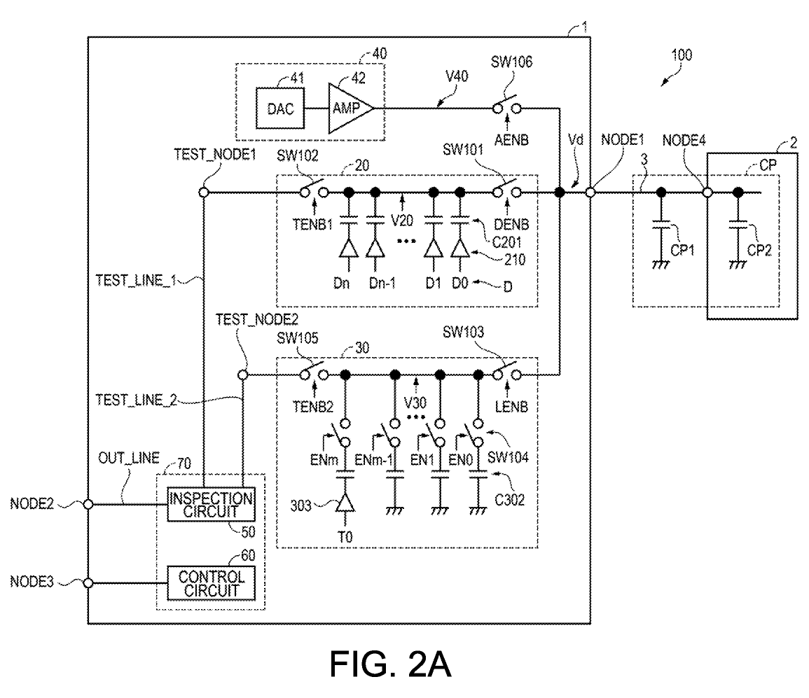

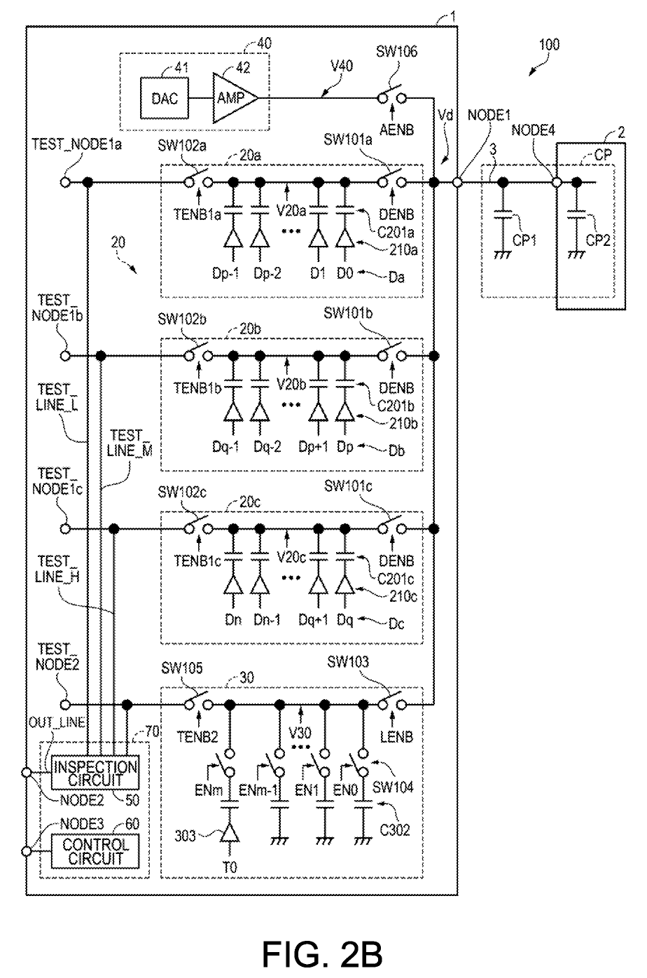

As illustrated in FIG. 1, the electro-optical device 100 includes a driver 1, an electro-optical panel 2, and a flexible substrate 3. The driver 1 includes a test circuit 70 (see FIG. 2A) described later.

The electro-optical device 100 is preferably used as a display device of a projector. The electro-optical device 100 may be used as a display device of a smartphone, a camera, a television, a car navigation device, a personal computer, a display, a point of sale (POS) terminal, a printer, a scanner, a copier, a video player, or an apparatus including a touch panel.

The electro-optical panel 2 is an active drive type transmissive liquid crystal display panel including pixels P in a display region TD and TFTs (Thin Film Transistors) as switching elements for the respective pixels P. The electro-optical panel 2 may be a reflective liquid crystal display panel or a transflective liquid crystal display panel. The electro-optical panel 2 may be a display device other than the liquid crystal display panel, for example, an organic EL display.

The pixels P are provided to correspond to intersections of scanning lines 2x and data lines 2y provided in a matrix. The electro-optical panel 2 includes an element substrate 21 and a counter substrate 22, and the flexible substrate 3 is mounted on a protruding portion 21a of the element substrate 21.

The driver 1 outputs a data voltage Vd for driving the electro-optical panel 2 to the electro-optical panel 2 based on a video signal representing image information. In the present embodiment, the driver 1 includes an integrated circuit device (IC). The integrated circuit device is, for example, an IC chip in which a circuit is formed on a silicon substrate, or a device in which an IC chip is housed in a package.

In the present embodiment, the driver 1 is mounted on the flexible substrate 3. That is, the data voltage Vd output from the driver 1 is supplied to the electro-optical panel 2 via the flexible substrate 3. Note that the driver 1 may be mounted on the protruding portion 21a of the electro-optical panel 2, or may be mounted on a rigid substrate (not illustrated) to supply the data voltage Vd to the electro-optical panel 2 via the flexible substrate 3.

The data voltage Vd, a power supply voltage, a timing signal, and the like are supplied to the electro-optical panel 2 via the flexible substrate 3, but part or all of the power supply voltage, the timing signal, and the like may be output by the driver 1.

### 1.2. Configuration of Driver 1

FIG. 2A is a block diagram showing a schematic configuration of the driver 1 including the test circuit 70. FIG. 2B is a block diagram showing another schematic configuration of the driver 1 including the test circuit 70.

As illustrated in FIG. 2A, the driver 1 includes a capacitance drive circuit 20, a balance capacitance circuit 30, a voltage drive circuit 40, an inspection circuit 50, a control circuit 60, and an output node NODE1 which is an output terminal for outputting the data voltage Vd. The output node NODE1 is electrically coupled to an input node NODE4 of the electro-optical panel 2 via the flexible substrate 3. The test circuit 70 of the present embodiment includes the inspection circuit 50 and the control circuit 60.

The capacitance drive circuit 20 outputs the data voltage Vd by charge redistribution of a capacitor. The balance capacitance circuit 30 is used for appropriately driving various electro-optical panels 2 having different electro-optical panel-side capacitive elements CP. The voltage drive circuit 40 outputs a voltage V40 based on a video signal representing image information as the data voltage Vd. In the present embodiment, the capacitance drive circuit 20 is an example of a drive circuit.

The capacitance drive circuit 20 is electrically coupled to the output node NODE1 via a switch SW101. The balance capacitance circuit 30 is electrically coupled to the output node NODE1 via a switch SW103. The voltage drive circuit 40 is electrically coupled to the output node NODE1 via a switch SW106.

When the driver 1 drives the electro-optical panel 2, the switch SW101 and the switch SW103 are turned on in a first period, and are turned off in a second period after the first period. In contrast, the switch SW106 is turned off in the first period, and is turned on in the second period after the first period. That is, the driver 1 outputs the data voltage Vd by driving by the capacitance drive circuit 20 in the first period, and outputs the data voltage Vd by driving by the voltage drive circuit 40 in the second period after the first period. Under the control, it is possible to drive the driver 1 at a high speed with high accuracy.

A control signal DENB is supplied from the control circuit 60 to the control terminal of the switch SW101, a control signal LENB is supplied from the control circuit 60 to the control terminal of the switch SW103, and a control signal AENB is supplied from the control circuit 60 to the control terminal of the switch SW106. That is, on/off of the switch SW101, the switch SW103, and the switch SW106 is controlled by the control circuit 60.

The capacitance drive circuit 20 is electrically coupled to a test node TEST_NODE1 via a switch SW102. The balance capacitance circuit 30 is electrically coupled to a test node TEST_NODE2 via a switch SW105. That is, the capacitance drive circuit 20 and the balance capacitance circuit 30 are coupled to the different test nodes. Therefore, since the driver 1 can inspect the capacitance drive circuit 20 and the balance capacitance circuit 30 in parallel, the inspection speed can be increased.

The test node TEST_NODE1 is electrically coupled to the inspection circuit 50 via a test line TEST_LINE1. The test node TEST_NODE2 is electrically coupled to the inspection circuit 50 via a test line TEST_LINE2.

The inspection circuit 50 is a circuit that inspects the accuracy of the capacitance drive circuit 20 and the balance capacitance circuit 30. The inspection result by the inspection circuit 50 is output to a node NODE2 via an output line OUT_LINE. It is possible to know the quality of the capacitance drive circuit 20 and the balance capacitance circuit 30, the occurrence of defects, and the like from the inspection result by the inspection circuit 50. Specifically, it is possible to know the quality of each of n capacitors C201 and m capacitors C302 from the inspection result by the inspection circuit 50.

The inspection circuit 50 is preferably formed on the same silicon substrate as the capacitance drive circuit 20 and the balance capacitance circuit 30, and the inspection circuit 50 can be formed at low cost on the same silicon substrate.

When the inspection circuit 50 inspects the capacitance drive circuit 20, the switch SW102 is turned on and the switch SW101 is turned off. Accordingly, an inspection voltage V20 is output to the inspection circuit 50 via the switch SW102, the test node TEST_NODE1, and the test line TEST_LINE1.

As described above, since the capacitance drive circuit 20 is separated from the output node NODE1 at the time of inspection, the influence of the output node NODE1 and the influence of the balance capacitance circuit 30 can be eliminated, and thus the amplitude of the inspection voltage can be increased. Therefore, according to the present embodiment, it is possible to increase the accuracy of the inspection of the capacitance drive circuit 20 by the inspection circuit 50.

When the inspection circuit 50 inspects the balance capacitance circuit 30, the switch SW105 is turned on and the switch SW103 is turned off. Accordingly, an inspection voltage V30 is output to the inspection circuit 50 via the switch SW105, the test node TEST_NODE2, and the test line TEST_LINE2.

As described above, since the balance capacitance circuit 30 is separated from the output node NODE1 at the time of inspection, the influence of the output node NODE1 and the influence of the capacitance drive circuit 20 can be eliminated, and thus the amplitude of the inspection voltage can be increased. Therefore, according to the present embodiment, it is possible to increase the accuracy of the inspection of the balance capacitance circuit 30 by the inspection circuit 50.

A control signal TENB1 is supplied from the control circuit 60 to the control terminal of the switch SW102, and a control signal TENB2 is supplied from the control circuit 60 to the control terminal of the switch SW105. That is, on/off of the switch SW102 and the switch SW105 is controlled by the control circuit 60.

The control circuit 60 is coupled to an input/output node NODE3. The control circuit 60 performs various kinds of control described above based on control information stored in a memory (not illustrated). The control information can be set or changed from outside via the input/output node NODE3.

As described above, in the present embodiment, the test circuit 70 includes the inspection circuit 50 and the control circuit 60. As described above, the inspection circuit 50 is preferably formed on the same silicon substrate as the capacitance drive circuit 20 and the balance capacitance circuit 30, but all or a part of the test circuit 70 may be formed on a silicon substrate different from that of the capacitance drive circuit 20 and the balance capacitance circuit 30. That is, the test circuit 70 may be provided in an IC chip different from the driver 1.

### 1.2.1. Configuration of Capacitance Drive Circuit 20

The capacitance drive circuit 20 is a circuit that outputs the data voltage Vd by charge redistribution of the capacitor. The capacitance drive circuit 20 outputs the data voltage Vd to the output node NODE1 via the switch SW101 having one end electrically coupled to the output node NODE1.

The capacitance drive circuit 20 includes the n capacitors C201 and a capacitor drive circuit 210 that drives the n capacitors C201 based on a video signal representing image information. Here, n is an integer of 1 or more, and for example, n may be set to the same number as the number of bits of gradation data D.

Each capacitance value of the n capacitors C201 is weighted by a power of 2 corresponding to each digit of bits D0, D1,..., Dn-1, and Dn of the gradation data D. Then, each drive unit of the capacitance drive circuit 20 outputs a low-level or high-level potential according to the bits D0, D1,..., Dn-1, and Dn, and thus the n capacitors C201 are driven by the potentials. The low-level potential is, for example, 0 V, and the high-level potential is, for example, 15 V.

This driving causes charge redistribution between the n capacitors C201 and the electro-optical panel-side capacitive element CP, and as a result, the data voltage Vd is output to the output node NODE1. The electro-optical panel-side capacitive element CP is determined by a substrate capacitive element CP1 and a panel capacitive element CP2.

The electro-optical panel-side capacitive element CP is the sum of capacitances seen from the output node NODE1. For example, the electro-optical panel-side capacitive element CP is obtained by adding the substrate capacitive element CP1 which is a parasitic capacitance of the flexible substrate 3 and the panel capacitive element CP2 which is a parasitic capacitance or pixel capacitance in the electro-optical panel 2. The TFT in the electro-optical panel 2 has a parasitic capacitance between the source and the gate. Since a large number of TFTs are coupled to the data lines 2y (see FIG. 1), the parasitic capacitances of the large number of TFTs are attached to the data lines 2y. Furthermore, parasitic capacitances are present between the data lines 2y and the scanning lines 2x. In the liquid crystal display panel, the pixel P has a capacitance. The sum of these is the panel capacitive element CP2.

### 1.2.2. Configuration of Balance Capacitance Circuit 30

The balance capacitance circuit 30 is a circuit which is a capacitance coupled to the output node NODE1 via the switch SW103 and whose capacitance value can be variably set.

The balance capacitance circuit 30 includes m switches SW104 and the m capacitors C302 for capacitance adjustment. Here, m is an integer of 1 or more.

One end of each of the m switches SW104 is electrically coupled to the other end of the switch SW103. Control signals EN0, EN1,..., ENm-1, and ENm are supplied from the control circuit 60 to the respective control terminals of the m switches SW104.

The balance capacitance circuit 30 is used to set the capacitance ratio between the capacitance of the n capacitors C201 and the electro-optical panel-side capacitive element CP to a predetermined value. With the balance capacitance circuit 30, the driver 1 can appropriately drive various electro-optical panels 2 having different electro-optical panel-side capacitive elements CP, and the versatility of the driver 1 can be increased.

The balance capacitance circuit 30 has a buffer 303. The buffer 303 is used to output the inspection voltage V30 at the time of inspecting the balance capacitance circuit 30. One end of the buffer 303 is coupled to one of the m capacitors C302, and a drive signal T0 is supplied to the other end of the buffer 303.

### 1.2.3. Configuration of Voltage Drive Circuit 40

The voltage drive circuit 40 includes a digital to analog Converter (DAC) 41 and an amplifier 42.

The DAC 41 generates and outputs a gradation voltage corresponding to each value of the gradation data D. When the gradation data D is, for example, 12 bits, 4096 levels of gradation voltages are generated and output.

The amplifier 42 performs at least one of amplification, inversion, inversion amplification, and impedance conversion on the gradation voltage output from the DAC 41, and outputs the voltage V40. The voltage V40 is output as the data voltage Vd from the output node NODE1 via the switch SW106.

### 1.2.4. Configuration of Modification of Driver 1

FIG. 2B shows a schematic configuration according to a modification of the driver 1. The driver 1 illustrated in FIG. 2B is different from the driver 1 illustrated in FIG. 2A in that the capacitance drive circuit 20 is divided into three of a capacitance drive circuit 20a, a capacitance drive circuit 20b, and a capacitance drive circuit 20c. The same configurations as those of the driver 1 illustrated in FIG. 2A may have the same signs, and the description thereof may be omitted.

The capacitance drive circuit 20a is used for bits D0, D1,..., Dp-2, Dp-1 of gradation data Da at the least significant bit (LSB) side among the three divisions of the gradation data D, the capacitance drive circuit 20b is used for bits Dp, Dp+1,..., Dq-2, Dq-1 of middle gradation data Db among the three divisions of the gradation data D, and the capacitance drive circuit 20c is used for bits Dq, Dq+1,..., Dn-1, Dn of gradation data Dc on the most significant bit (MSB) side among the three divisions of the gradation data D. Here, q is an integer smaller than n, and p is an integer smaller than q.

When the inspection circuit 50 inspects the capacitance drive circuit 20a, the control circuit 60 outputs control signals TENB1a and DENB to turn on a switch SW102a and turn off a switch SW101a. Accordingly, an inspection voltage V20a is output to the inspection circuit 50 via the switch SW102a, a test node TEST_NODE1a, and a test line TEST_LINE_L. In the present embodiment, the test node TEST_NODE1a is an example of a first test node.

When the inspection circuit 50 inspects the capacitance drive circuit 20b, the control circuit 60 outputs control signals TENB1b and DENB to turn on a switch SW102b and turn off a switch SW101b. Accordingly, an inspection voltage V20b is output to the inspection circuit 50 via the switch SW102b, a test node TEST_NODE1b, and a test line TEST_LINE_M. In the present embodiment, the test node TEST_NODE1b is an example of a second test node.

When the inspection circuit 50 inspects the capacitance drive circuit 20c, the control circuit 60 outputs control signals TENB1c and DENB to turn on a switch SW102c and turn off a switch SW101c. Accordingly, an inspection voltage V20c is output to the inspection circuit 50 via the switch SW102c, a test node TEST_NODE1c, and a test line TEST_LINE_H.

Here, the inspection voltage V20a is lower than the inspection voltage V20b, and the inspection voltage V20c is higher than the inspection voltage V20b.

### 1.3. Regarding Configuration of Test Circuit 70

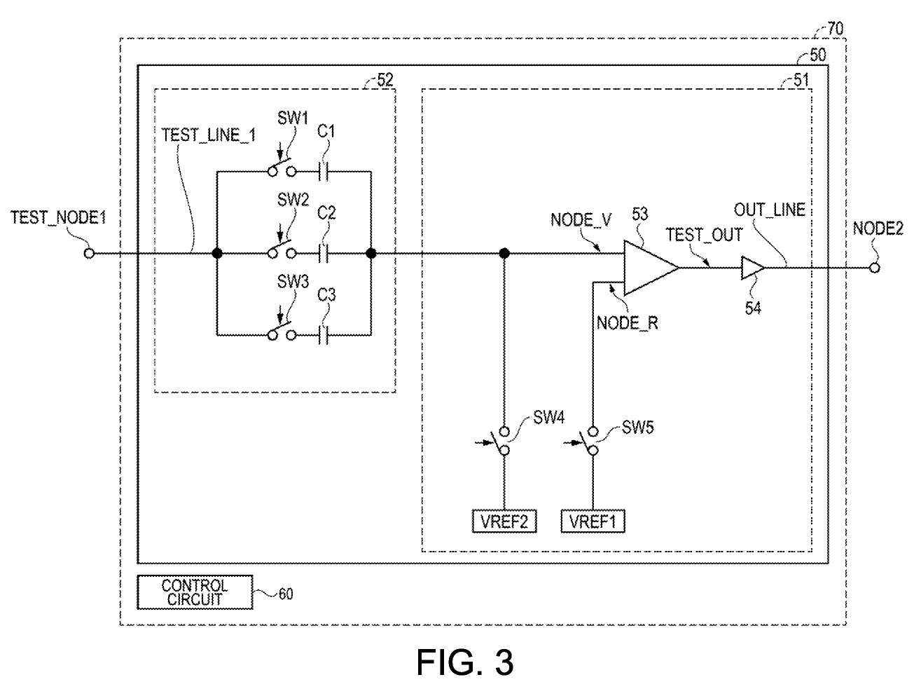

FIG. 3 is a circuit diagram of the test circuit 70.

As shown in FIG. 3, the test circuit 70 includes the inspection circuit 50 and the control circuit 60.

The inspection circuit 50 has a first circuit 51 including an amplifier 53, and a second circuit 52 including capacitive elements C1, C2, and C3 and switches SW1, SW2, and SW3.

The amplifier 53 compares the potential of an input node NODE_V with the potential of an input node NODE_R, and outputs a comparison result to an output node TEST_OUT. That is, in the present embodiment, the amplifier 53 is a comparator, and outputs a binary logic level signal at a high level or a low level based on the comparison result. The comparison result output from the output node TEST_OUT is output to the node NODE2 via a buffer 54 and the output line OUT_LINE.

A reference potential VREF1 is supplied to the input node NODE_R of the amplifier 53 via a switch SW5. The reference potential VREF1 may be, for example, a ground potential.

An initial potential VREF2 is supplied to the input node NODE_V of the amplifier 53 via a switch SW4, and the input node is electrically coupled to the test node TEST_NODE1 via the second circuit 52.

In the present embodiment, the input node NODE_V of the amplifier 53 is an example of a first input node, the input node NODE_R is an example of a second input node, and the output node TEST_OUT is an example of an output node. The initial potential VREF2 is an example of a first potential, and the reference potential VREF1 is an example of a second potential. The switch SW4 is an example of a first switch, and the switch SW5 is an example of a second switch.

The second circuit 52 is provided between the test node TEST_NODE1 and the input node NODE_V of the amplifier 53, changes the amplitude of the inspection voltage V20 (see FIG. 2A) applied via the test node TEST_NODE1 and the test line TEST_LINE1 to a desired amplitude smaller than the amplitude of the inspection voltage V20, and outputs the inspection voltage to the input node NODE_V.

The second circuit 52 is a variable capacitance circuit and includes the capacitive elements C1, C2, and C3 provided in parallel and the switches SW1, SW2, and SW3 provided in series with the capacitive elements C1, C2, and C3, respectively. In the second circuit 52 of the present embodiment, the capacitance of the capacitive element C1 is the largest, the capacitance of the capacitive element C3 is the smallest, and the capacitance of the capacitive element C2 is intermediate between the capacitance of the capacitive element C1 and the capacitance of the capacitive element C3. The number of the capacitive elements C1, C2, and C3 of the second circuit 52 is not limited to three, and may be two or four or more. In the present embodiment, the capacitive element C1 is an example of a first capacitive element, and the switch SW1 is an example of a third switch. The capacitive element C2 is an example of a second capacitive element, and the switch SW2 is an example of a fourth switch.

The second circuit 52 is supplied with the inspection voltage V20 from the capacitance drive circuit 20 (see FIG. 2A) via the test node TEST_NODE1 and the test line TEST_LINE1, and the input node NODE_V of the amplifier 53 is supplied with a voltage obtained by dividing the inspection voltage V20 according to the capacitance ratio between the capacitance of the second circuit 52 and the capacitance of the first circuit 51, specifically, the parasitic capacitance of the switch SW4. Therefore, the second circuit 52 can set the voltage applied to the input node NODE_V of the amplifier 53 to be lower than the inspection voltage V20.

As described above, the voltage applied to the input node NODE_V of the amplifier 53 is lower than the inspection voltage V20 applied to the second circuit 52 via the test node TEST_NODE1 and the test line TEST_LINE1.

Therefore, the withstand voltage of the amplifier 53 can be set to be lower than the inspection voltage V20. Similarly, the withstand voltages of the switch SW4 and the switch SW5 can be set to be lower than the inspection voltage V20. That is, the first circuit 51 can be formed as a circuit having a lower withstand voltage than the second circuit 52. The second circuit 52 is a circuit having a higher withstand voltage than the first circuit 51, and the withstand voltages of the transistors used for the switches SW1, SW2, and SW3 are equal to or higher than the voltage of the inspection voltage V20.

In the present embodiment, the first circuit 51 is formed as the circuit having the lower withstand voltage than the voltage of the inspection voltage V20, and thus it is possible to reduce a circuit area necessary for forming the first circuit 51, and it is possible to contribute to miniaturization of the IC chip. Furthermore, the first circuit 51 is formed as a circuit having the lower withstand voltage than the voltage of the inspection voltage V20, and thus it is possible to operate the first circuit 51 faster, and it is possible to shorten the inspection time.

In the present embodiment, the voltage of the inspection voltage V20 applied to the second circuit 52 via the test line TEST_LINE1 can be changed such that the voltage output from the second circuit 52 to the input node NODE_V of the amplifier 53 falls within the withstand voltage range of the first circuit 51 by appropriately selecting the capacitive elements C1, C2, and C3 of the second circuit 52 by the switches SW1, SW2, and SW3. In addition, by appropriately selecting the capacitive elements C1, C2, and C3 of the second circuit 52 according to the voltage of the test target voltage V20, the voltage output from the second circuit 52 to the input node NODE_V of the amplifier 53 can be set to a voltage suitable for the test, so that the accuracy of the test can be increased.

### 1.4. Regarding Operation of Test Circuit 70

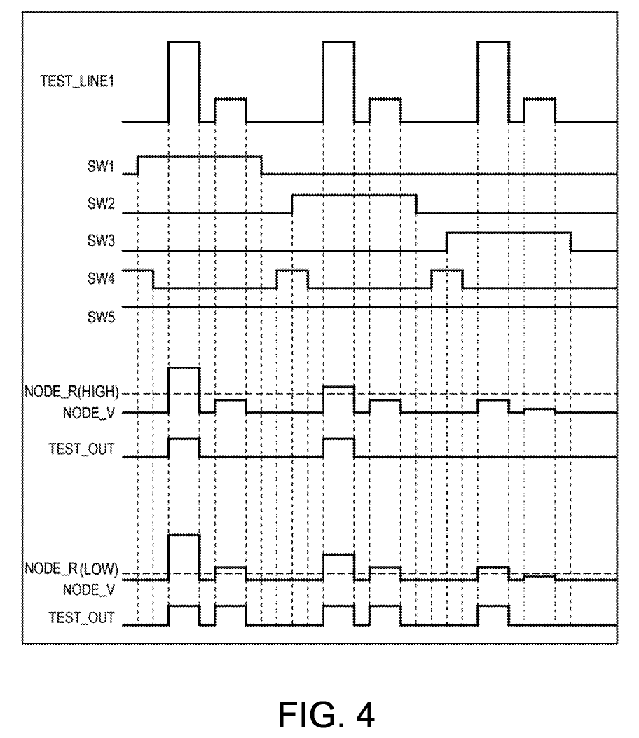

FIG. 4 is a timing chart showing an operation of the test circuit 70.

In FIG. 4, the waveform indicated by TEST_LINE1 is the waveform of the test target voltage V20 applied to the second circuit 52 via the test node TEST_NODE1 and the test line TEST_LINE1.

The waveforms indicated by SW1, SW2, SW3, and SW4 are the waveforms of the control signals output from the control circuit 60 and input to the control terminals of the switches SW1, SW2, SW3, and SW4, and the switches SW1, SW2, SW3, and SW4 are turned on when the control signals are at the high level, and are turned off when the control signals are at the low level.

The waveform indicated by NODE_V is the waveform of the voltage applied to the input node NODE_V of the amplifier 53.

The waveforms indicated by NODE_R (HIGH) and NODE_R (LOW) are the waveforms of the voltages of the reference potentials VREF1 applied to the input node NODE_R of the amplifier 53, and the voltage of the reference potential VREF1 is lower for NODE_R (LOW) than for NODE_R (HIGH). The sensitivity of the amplifier 53 can be changed by changing the voltage of the reference potential VREF1. For example, by reducing the potential difference between the reference potential VREF1 and the initial potential VREF2, the amplifier 53 can capture a small amplitude and output a test result.

The waveform indicated by TEST_OUT is the waveform of the voltage output from the output node TEST_OUT of the amplifier 53. In comparison between the potential of the input node NODE_V and the potential of the input node NODE_R, when the potential of the input node NODE_V is higher, a high-level signal is output, and when the potential of the input node NODE_V is lower, a low-level signal is output.

When the test circuit 70 is operated, the control signal indicated by SW5 is set at the high level in the entire period, and the switch SW5 is turned on.

In the example illustrated in FIG. 4, the control signals indicated by SW1, SW2, and SW3 are sequentially set at the high level, and the capacitive element C1, the capacitive element C2, and the capacitive element C3 are sequentially electrically coupled between the test line TEST_LINE1 and the input node NODE_V of the amplifier 53. All or any two of the capacitive elements C1, C2, and C3 may be electrically coupled between the test line TEST_LINE1 and the input node NODE_V of the amplifier 53 at the same time. On or off of the switches SW1, SW2, and SW3 is controlled so that the capacitive elements C1, C2, and C3 necessary for accurate inspection are selected.

In a period in which the control signal indicated by SW1, SW2, or SW3 is at the high level, that is, in a period in which the capacitive element C1, the capacitive element C2, or the capacitive element C3 is selected, the inspection voltage V20 having a high amplitude and the inspection voltage V20 having a low amplitude are sequentially input to the test line TEST_LINE1.

As illustrated in FIG. 4, a divided voltage is applied to the input node NODE_V of the amplifier 53 according to the capacitance ratio between the capacitive element C1, the capacitive element C2, or the capacitive element C3 and the parasitic capacitance of the second circuit 52.

In the present embodiment, since the capacitance of the capacitive element C1 is the largest and the capacitance of the capacitive element C3 is the smallest, the voltage applied to the input node NODE_V is the largest when the capacitive element C1 is selected and is the smallest when the capacitive element C3 is selected.

Therefore, a high-level or low-level signal is output from the output node TEST_OUT according to the voltages of the reference potential VREF1 indicated by NODE_R (HIGH) and NODE_R (LOW).

Therefore, by setting the reference potential VREF1 to an appropriate voltage, it is possible to determine the accuracy of the inspection voltage V20 output from the capacitance drive circuit 20, in other words, whether there is a failure in the capacitance drive circuit 20, by the signal output from the output node TEST_OUT.

As described above, according to the test circuit 70 of the present embodiment, the following effects can be obtained.

The test circuit 70 of the present embodiment includes the first circuit 51 having the amplifier 53 having the input node NODE_V as the first input node, the input node NODE_R as the second input node, and the output node TEST_OUT, the switch SW4 as the first switch having one end electrically coupled to the input node NODE_V and the other end to which the initial potential VREF2 as the first potential is applied, and the switch SW5 as the second switch having one end electrically coupled to the input node NODE_R and the other end to which the reference potential VREF1 as the second potential is applied, the second circuit 52 having the capacitive element C1 as the first capacitive element provided between the test node TEST_NODE1 and the input node NODE_V and having one end electrically coupled to the input node NODE_V, and the switch SW1 as the third switch having one end electrically coupled to the other end of the capacitive element C1 and the other end electrically coupled to the test node TEST_NODE1, the capacitive element C2 as the second capacitive element having one end electrically coupled to the input node NODE_V, and the switch SW2 as the fourth switch having one end electrically coupled to the other end of the capacitive element C2 and the other end electrically coupled to the test node TEST_NODE1, and the control circuit 60 that controls the first circuit 51 and the second circuit 52, wherein the withstand voltage of the amplifier 53 is lower than the voltage applied to the test node TEST_NODE1, and the capacitance of the capacitive element C2 is smaller than the capacitance of the capacitive element C1.

As described above, the test circuit 70 of the present embodiment includes the capacitive element C1 and the capacitive element C2 provided in parallel between the test node TEST_NODE1 and the input node NODE_V, and the switch SW1 and the switch SW2 coupled to the capacitive element C1 and the capacitive element C2. Therefore, the withstand voltage of the amplifier 53 can be set to be lower than the voltage applied to the test node TEST_NODE1. Furthermore, since the capacitive element C1 and the capacitive element C2 have different capacitances, by appropriately selecting the capacitive element C1 and the capacitive element C2 by the switch SW1 and the switch SW2, the voltage applied to the input node NODE_V can be set to a desired voltage lower than the inspection voltage V20 applied to the test node TEST_NODE1.

Therefore, according to the test circuit 70 of the present embodiment, since the amplifier 53 can be set to the low withstand voltage, the circuit area of the test circuit 70 can be reduced, and the high-speed and high-accuracy test circuit 70 can be implemented. Furthermore, even when the amplitude of the inspection voltage V20 greatly changes, sufficient sensitivity can be ensured, and highly accurate measurement can be performed.

In the test circuit 70 of the present embodiment, the control circuit 60 controls the conduction states of the switch SW1 and the switch SW2 according to the voltage applied to the test node TEST_NODE1.

Therefore, the test circuit 70 of the present embodiment is controlled by the control circuit 60, thereby implementing the high-speed and high-precision test circuit 70.

In the test circuit 70 of the present embodiment, the reference potential VREF1 is the ground potential. Therefore, the test circuit 70 can be stably operated.

The electro-optical device 100 of the present embodiment includes the electro-optical panel 2, the capacitance drive circuit 20 as the drive circuit that drives the electro-optical panel 2, and the above-described test circuit 70.

Therefore, since the electro-optical device 100 of the embodiment can inspect the capacitance drive circuit 20 by the test circuit 70, it is possible to implement the electro-optical device 100 having excellent quality.

In the electro-optical device 100 of the embodiment, when the electro-optical panel 2 is driven by the capacitance drive circuit 20, the switch SW5 is turned off.

Therefore, in the electro-optical device 100 of the embodiment, when the electro-optical panel 2 is driven by the capacitance drive circuit 20, the test circuit 70 is off, and thus it is possible to implement the electro-optical device 100 with low power consumption.

### 2. Embodiment 2

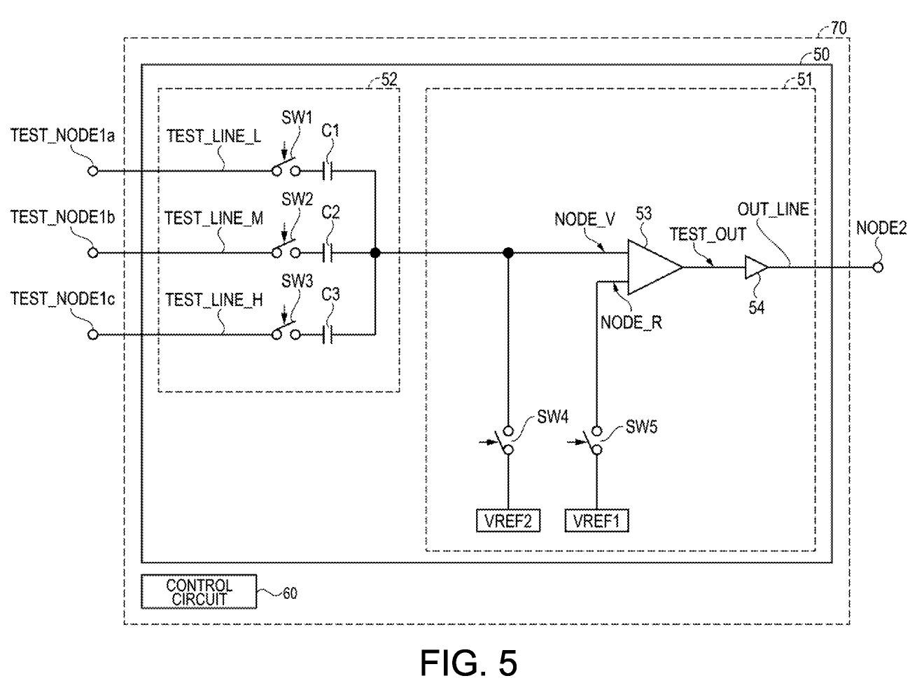

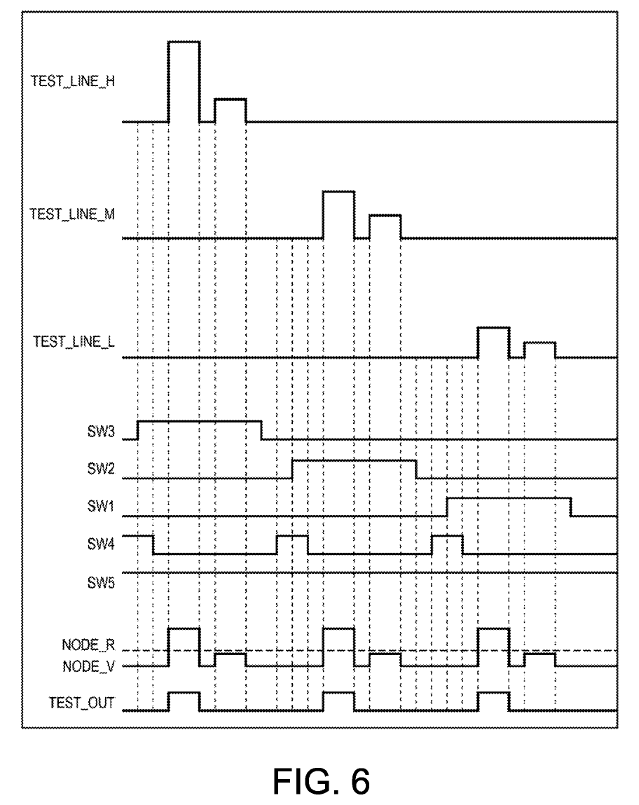

Next, a test circuit 70 according to Embodiment 2 will be described with reference to FIGS. 5 and 6. FIG. 5 is a circuit diagram of the test circuit 70 according to Embodiment 2. FIG. 6 is a timing chart showing an operation of the test circuit 70 according to Embodiment 2.

The test circuit 70 according to Embodiment 2 is used in the driver 1 illustrated in FIG. 2B, and is different from the test circuit 70 according to Embodiment 1 in that the switches SW1, SW2, and SW3 are electrically coupled to different test nodes TEST_NODE1a, TEST_NODE1b, and TEST_NODE1c and test lines TEST_LINE_L, TEST_LINE_M, and TEST_LINE_H, respectively. The same configurations as those of Embodiment 1 may have the same signs, and the description thereof may be omitted.

The switch SW1 is electrically coupled to the test node TEST_NODE1a and the test line TEST_LINE_L. The inspection voltage V20a is applied to the test line TEST_LINE_L from the capacitance drive circuit 20a that is used for the least significant bit side among the three divisions of the gradation data D.

The switch SW2 is electrically coupled to the test node TEST_NODE1b and the test line TEST_LINE_M. The inspection voltage V20b is applied to the test line TEST_LINE_M from the capacitance drive circuit 20b that is used for the middle bits among the three divisions of the gradation data D.

The switch SW3 is electrically coupled to the test node TEST_NODE1c and the test line TEST_LINE_H. The inspection voltage V20c is applied to the test line TEST_LINE_H from the capacitance drive circuit 20c that is used for the most significant bit side among the three divisions of the gradation data D.

As illustrated in FIG. 6, the inspection voltage V20c having the highest amplitude is applied to the test line TEST_LINE_H, and the inspection voltage V20a having the lowest amplitude is applied to the test line TEST_LINE_L, but the amplitude of the voltage applied to the input node NODE_V of the amplifier 53 can be made uniform by appropriately selecting each capacitance of the capacitive element C1, the capacitive element C2, and the capacitive element C3. Therefore, according to the test circuit 70 of Embodiment 2, it is possible to perform an appropriate test on each of the test voltages V20a, V20b, and V20c having different amplitudes.

As described above, according to the test circuit 70 of Embodiment 2, the following effects can be obtained in addition to the effects of the test circuit 70 of Embodiment 1.

In the test circuit 70 of Embodiment 2, the test node TEST_NODE1 includes the test node TEST_NODE1a as the first test node and the test node TEST_NODE1b as the second test node, the test node TEST_NODE1a is electrically coupled to the other end of the switch SW1, and the test node TEST_NODE1b is electrically coupled to the other end of the switch SW2.

As described above, the test circuit 70 of the present embodiment can electrically couple the capacitive element C1 or the capacitive element C2 appropriate to each of the test voltage V20a and the test voltage V20b. Therefore, it is possible to implement the test circuit 70 with high speed and high accuracy. Furthermore, even when the amplitude of the inspection voltage V20 greatly changes, it is possible to secure sufficient sensitivity and perform highly accurate measurement.

### 3. Embodiment 3

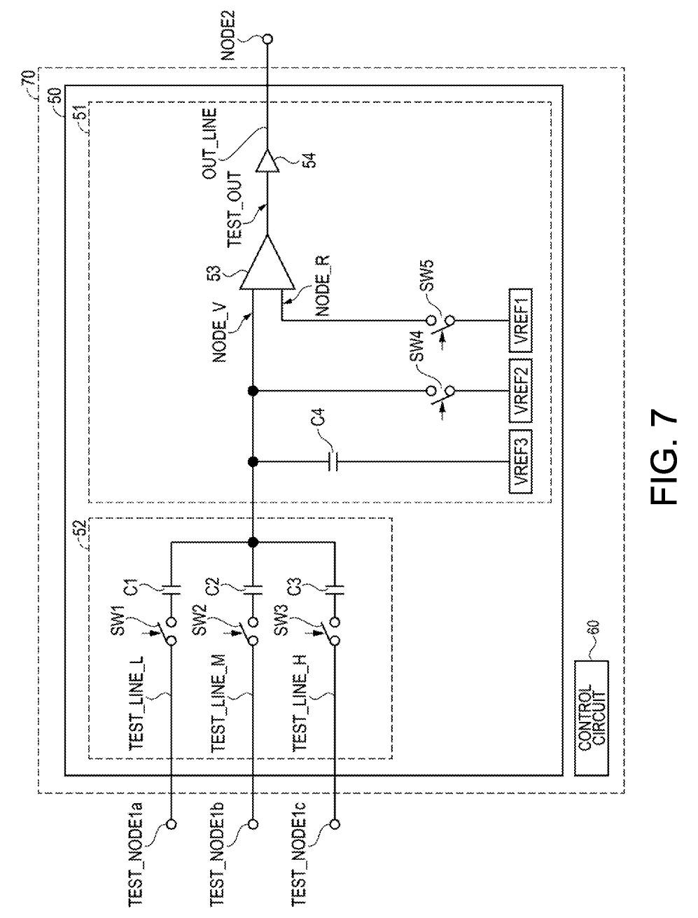

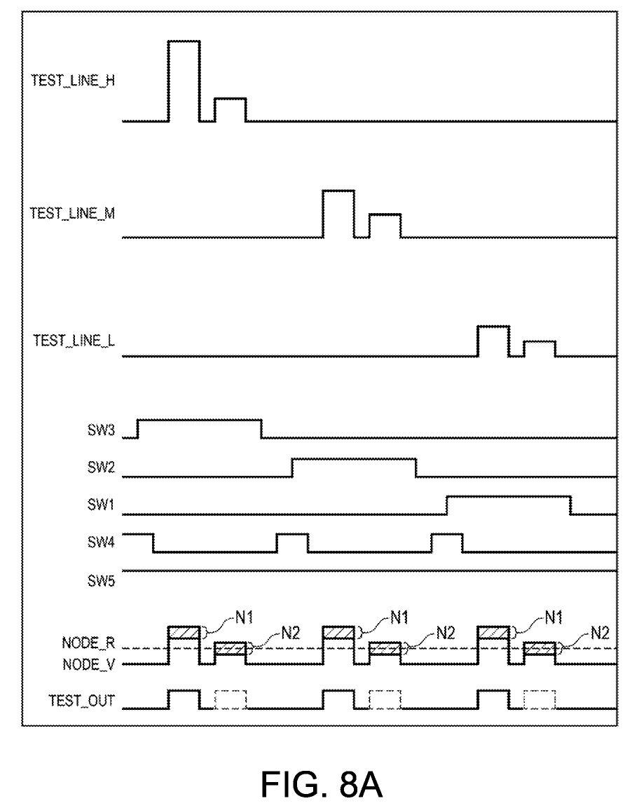

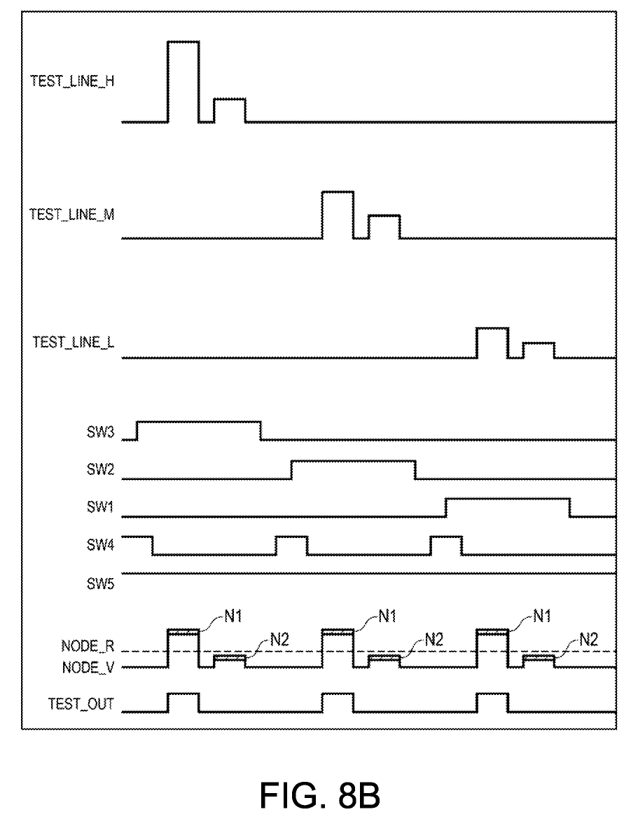

Next, a test circuit 70 according to Embodiment 3 will be described with reference to FIGS. 7, 8A, and 8B . FIG. 7 is a circuit diagram of the test circuit 70 according to Embodiment 3. FIG. 8A is a timing chart showing an operation of a test circuit of a comparative example of the test circuit 70 of Embodiment 3. FIG. 8B is a timing chart showing an operation of the test circuit 70 according to Embodiment 3.

The test circuit 70 according to Embodiment 3 is used in the driver 1 illustrated in FIG. 2B, and is different from the test circuit 70 according to Embodiment 1 in that the switches SW1, SW2, and SW3 are electrically coupled to different test nodes TEST_NODE1a, TEST_NODE1b, and TEST_NODE1c and test lines TEST_LINE_L, TEST_LINE_M, and TEST_LINE_H, and is different from the test circuit 70 according to Embodiment 2 in that a capacitive element C4 is electrically coupled to the input node NODE_V of the amplifier 53. The same configurations as those in Embodiment 1 and Embodiment 2 may have the same signs, and the description thereof may be omitted.

The capacitive element C4 is formed of a metal insulation metal (MIM) capacitor. The capacitive element C4 has one end electrically coupled to the input node NODE_V of the amplifier 53 and the other end electrically coupled to a fixed potential VREF3. The fixed potential VREF3 is, for example, VSS. In the present embodiment, the fixed potential VREF3 is an example of a third potential, and the capacitive element C4 is an example of a third capacitive element.

When the capacitance ratio between the capacitance of the second circuit 52 and the capacitance of the first circuit 51, that is, the input capacitance of the input node NODE_V of the amplifier 53 is large, the voltage of the input node NODE_V of the amplifier 53 greatly fluctuates due to the influence of noise as indicated by ranges N1 and N2 in FIG. 8A. In the example illustrated in FIG. 8A, since the portion indicated by the range N2 overlaps the input node NODE_R, the output of the output node TEST_OUT of the amplifier 53 is not determined. The example illustrated in FIG. 8A is an example in which the capacitive element C4 is not provided, and the capacitance ratio between the capacitance of the second circuit 52 and the capacitance of the first circuit 51 is larger than that in Embodiment 3.

In contrast, in Embodiment 3, since the capacitive element C4 electrically coupled to the input node NODE_V is provided, the capacitance ratio between the capacitance of the second circuit 52 and the capacitance of the first circuit 51 can be reduced. Therefore, as indicated by the ranges N1 and N2 in FIG. 8B, the fluctuations of the voltage of the input node NODE_V of the amplifier 53 can be reduced. Thus, it is possible to perform a test by the amplifier 53 with high accuracy.

As described above, according to the test circuit 70 of Embodiment 3, the following effects can be further obtained in addition to the effects of the test circuits 70 of Embodiment 1 and Embodiment 2.

The test circuit 70 of Embodiment 3 further has the capacitive element C4 as the third capacitive element having one end electrically coupled to the input node NODE_V and the other end to which the fixed potential VREF3 as the third potential is applied.

According to the test circuit 70 of Embodiment 3, since the influence of noise can be suppressed, it is possible to implement the test circuit 70 with high accuracy.

### 4. Embodiment 4

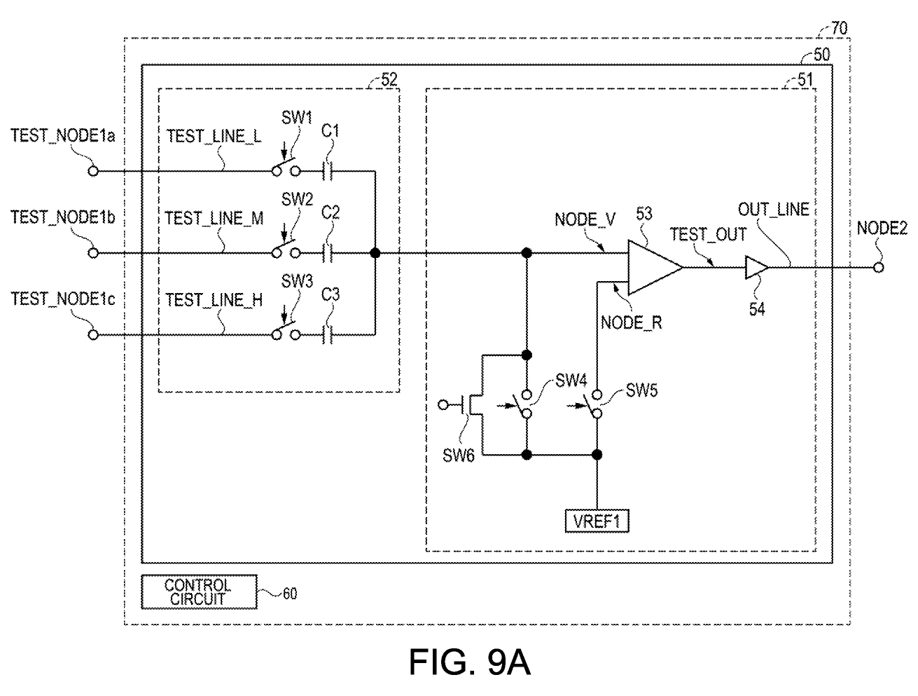

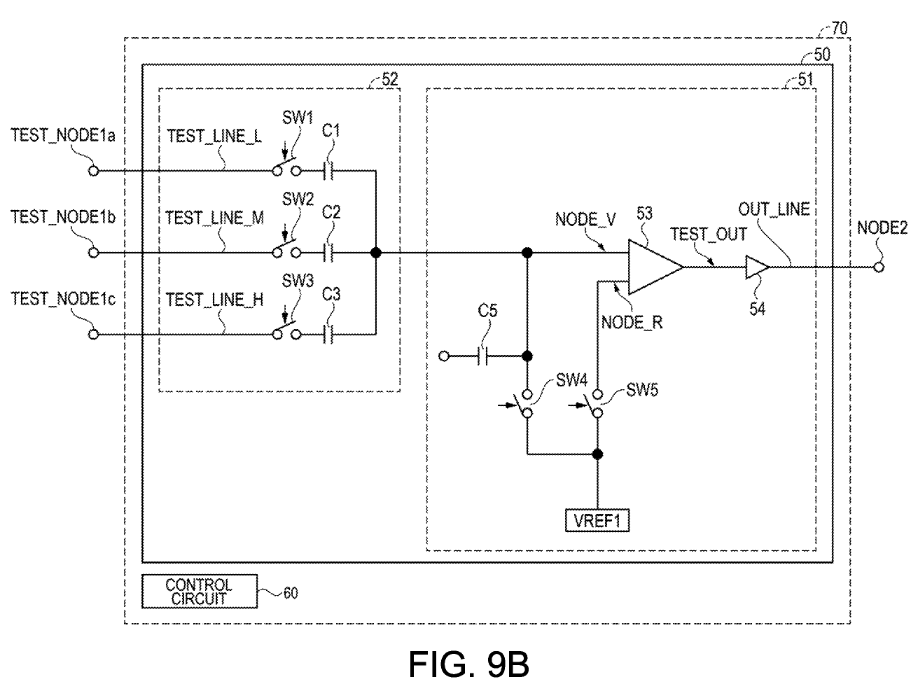

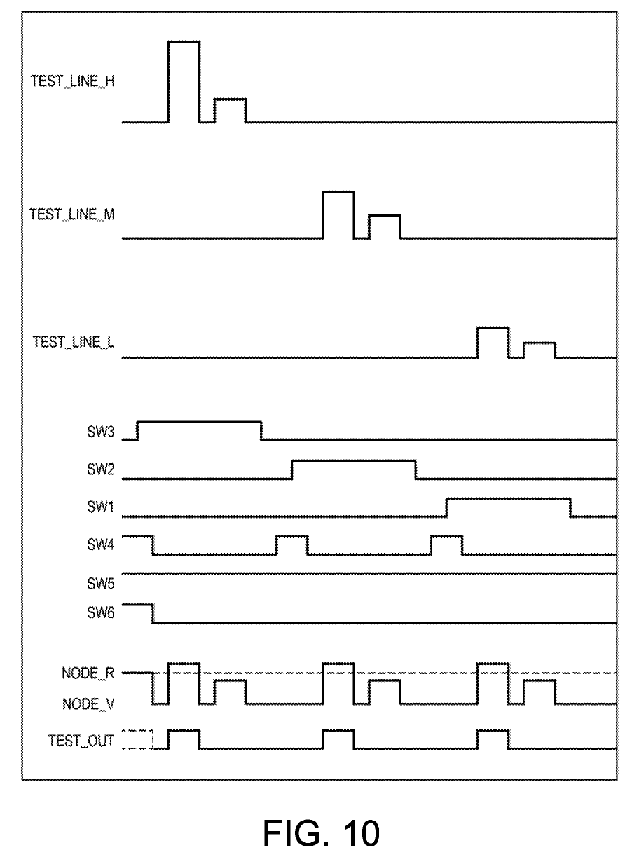

Next, a test circuit 70 according to Embodiment 4 will be described with reference to FIGS. 9A, 9B, and 10. FIG. 9A is a circuit diagram of the test circuit 70 according to Embodiment 4. FIG. 9B is a circuit diagram of a test circuit 70 according to a modification of Embodiment 4. FIG. 10 is a timing chart showing an operation of the test circuit 70 according to Embodiment 4.

The test circuit 70 according to Embodiment 4 is different from the test circuits 70 according to the Embodiment 1 to Embodiment 3 in that the input node NODE_V of the amplifier 53 is electrically coupled to the same power supply as the input node NODE_R of the amplifier 53, specifically, the reference potential VREF1. The same configurations as those in Embodiment 1 to Embodiment 3 may have the same signs, and the description thereof may be omitted.

As illustrated in FIG. 9A, the input node NODE_V of the amplifier 53 is electrically coupled to the same reference potential VREF1 as that of the input node NODE_R of the amplifier 53 via the switch SW4. A switch SW6 is coupled in parallel to the switch SW4. The switch SW6 is a transistor and is used to provide a potential difference between the potential of the input node NODE_V and the potential of the input node NODE_R of the amplifier 53. Specifically, when the switch SW6 is turned off, the potential of the input node NODE_V is lowered by pushdown caused by the drain capacitance of the switch SW6, thereby providing a potential difference between the potential of the input node NODE_V and the potential of the input node NODE_R of the amplifier 53.

The switch SW6 can be replaced with a capacitor. FIG. 9B illustrates a circuit configuration of the test circuit 70 of the modification of Embodiment 4, and in the modification, a capacitive element C5 is provided instead of the switch SW6. The capacitive element C5 is electrically coupled to the input node NODE_V of the amplifier 53.

In Embodiment 4, the configuration using the switch SW6 and the configuration using the capacitive element C5 have been described as the configurations of applying the potential difference between the potential of the input node NODE_V and the potential of the input node NODE_R of the amplifier 53, but the configuration using the switch SW6 is preferable. Since the potential difference between the potential of the input node NODE_V and the potential of the input node NODE_R of the amplifier 53 may be small, the capacitance required to provide the potential difference may also be small. This is because, when the small capacitance is formed in the integrated circuit device, it is easy to make the drain capacitance of the switch SW6 smaller than the capacitance of the capacitive element C5.

When the test circuit 70 of Embodiment 4 is operated, as illustrated in FIG. 10, first, the control signals indicated by SW4, SW5, and SW6 are set at the high level, and the switch SW4, the switch SW5, and the switch SW6 are turned on. The reference potential VREF1 is supplied to the input node NODE_V of the amplifier 53 via the switch SW4,and the input node NODE_V and the input node NODE_R of the amplifier 53 have the same potential. Since the input node NODE_V and the input node NODE_R of the amplifier 53 have the same potential, the output of the output node TEST_OUT of the amplifier 53 is not determined.

Thereafter, the control signals indicated by SW4 and SW6 are set at the low level, so that the switch SW4 and the switch SW6 are turned off. When the switch SW6 is turned off, the potential of the input node NODE_V decreases as illustrated in FIG. 10 due to pushdown caused by the drain capacitance. Accordingly, a potential difference occurs between the potential of the input node NODE_V and the potential of the input node NODE_R of the amplifier 53, and the amplifier 53 can output a stable signal from the output node TEST_OUT.

As described above, according to the test circuit 70 of Embodiment 4, the following effects can be further obtained in addition to the effects of the test circuits 70 of Embodiment 1 to Embodiment 3.

In the test circuit 70 of Embodiment 4, the other end of the switch SW4 and the other end of the switch SW5 are electrically coupled to the reference potential VREF1 as the same power supply.

Therefore, since the test circuit 70 can be formed of the simple circuit, the circuit area of the test circuit 70 can be reduced.

### 5. Embodiment 5

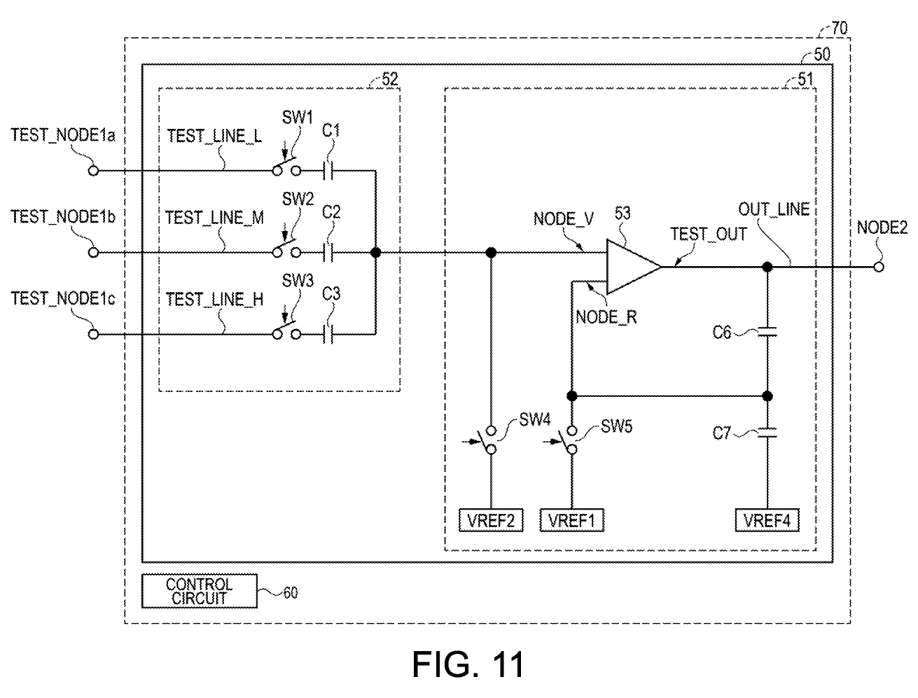

Next, a test circuit 70 according to Embodiment 5 will be described with reference to FIG. 11. FIG. 11 is a circuit diagram of the test circuit 70 according to Embodiment 5.

The test circuit 70 according to Embodiment 5 is different from the test circuits 70 according to Embodiment 1 to Embodiment 4 in that the amplifier 53 includes a feedback circuit and forms a differential amplifier circuit. The same configurations as those in Embodiment 1 to Embodiment 4 may have the same signs, and the description thereof may be omitted.

As illustrated in FIG. 11, in the test circuit 70 according to Embodiment 5, the amplifier 53 has the feedback circuit. The feedback circuit includes a capacitive element C6 having one end electrically coupled to the output node TEST_OUT of the amplifier 53 and the other end electrically coupled to the input node NODE_R, and a capacitive element C7 having one end electrically coupled to the input node NODE_R and the other end to which a fixed potential VREF4 is applied. In Embodiment 5, the capacitive element C6 is an example of a fourth capacitive element, the capacitive element C7 is an example of a fifth capacitive element, and the fixed potential VREF4 is an example of a fourth potential.

The amplifier 53 amplifies and outputs the potential difference between the input node NODE_V and the input node NODE_R according to the capacitances of the capacitive element C6 and the capacitive element C7. Therefore, by adjusting the voltage of the reference potential VREF1 to a predetermined voltage as it should be, it is possible to know a deviation in the inspection voltage V20 output from the capacitance drive circuit 20. The capacitive element C6 and the capacitive element C7 may be formed of resistors.

As described above, according to the test circuit 70 of Embodiment 5, the following effects can be further obtained in addition to the effects of the test circuits 70 of Embodiment 1 to Embodiment 4.

The test circuit 70 of Embodiment 5 further includes the capacitive element C6 as the fourth capacitive element having one end electrically coupled to the output node TEST_OUT and the other end electrically coupled to the input node NODE_R, and the capacitive element C7 as the fifth capacitive element having one end electrically coupled to the input node NODE_R and the other end to which the fixed potential VREF4 as the fourth potential is applied.

As described above, according to the test circuit 70 of Embodiment 5, the potential difference between the input node NODE_V and the input node NODE_R is amplified and output with the amplification factor corresponding to the capacitances of the capacitive element C6 and the capacitive element C7. Therefore, by adjusting the voltage of the reference potential VREF1 to a predetermined voltage as it should be, it is possible to know a deviation in the inspection voltage V20 output from the capacitance drive circuit 20.

### 6. Embodiment 6

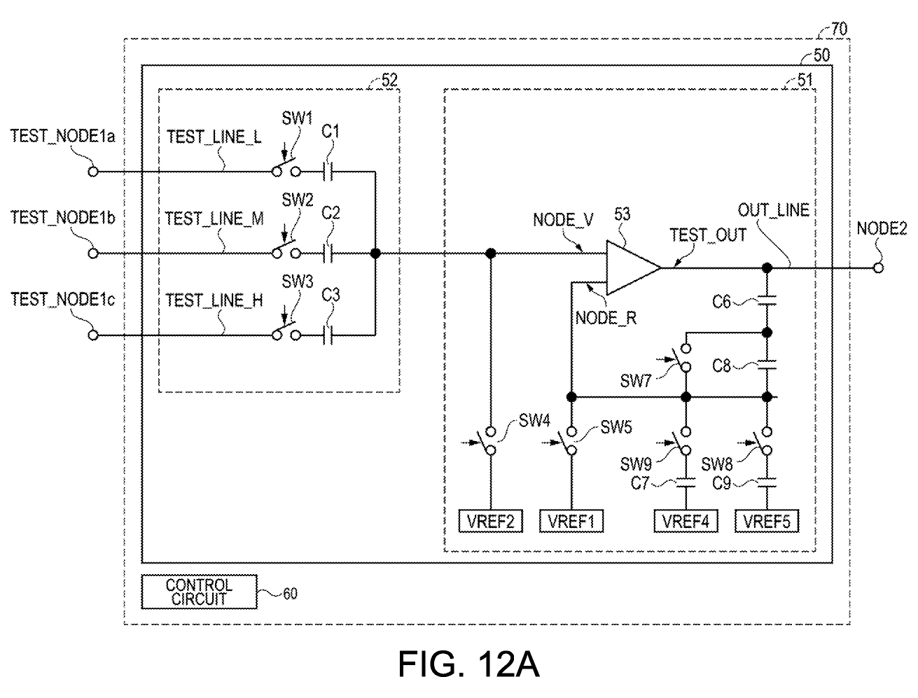

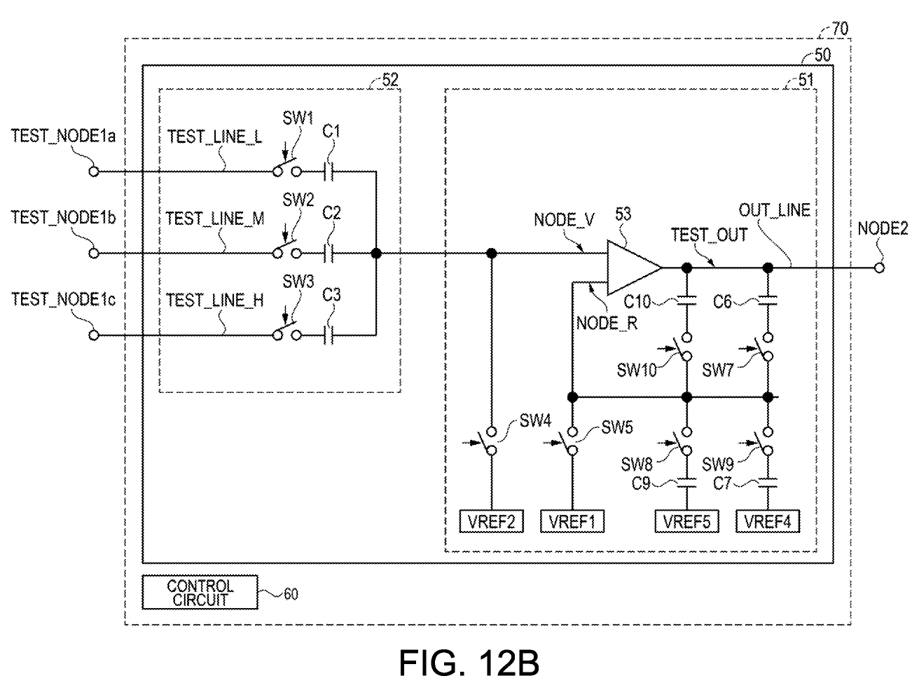

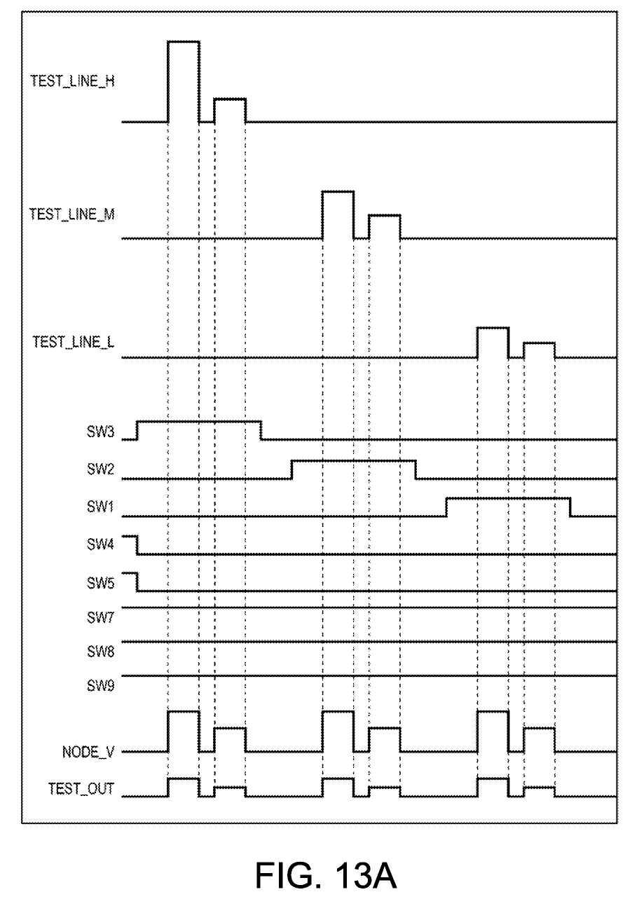

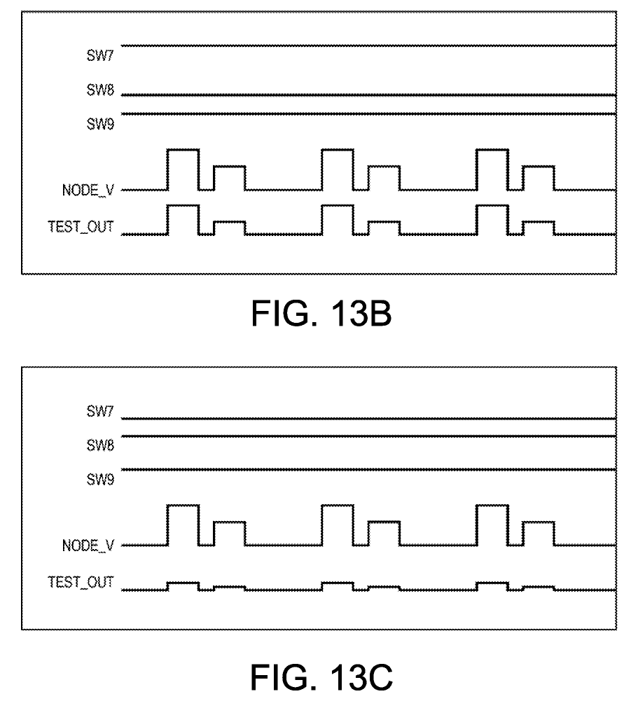

Next, a test circuit 70 according to Embodiment 6 will be described with reference to FIGS. 12A to 13C. FIG. 12A is a circuit diagram of the test circuit 70 according to Embodiment 6. FIG. 12B is a circuit diagram of a test circuit 70 according to a modification of Embodiment 6. FIG. 13A is a timing chart showing an operation of the test circuit 70 according to Embodiment 6. FIG. 13B is a timing chart showing the operation of the test circuit 70 according to Embodiment 6. FIG. 13C is a timing chart showing the operation of the test circuit 70 according to Embodiment 6.

The test circuit 70 according to Embodiment 6 is common to the test circuit 70 according to Embodiment 5 in that the amplifier 53 has a feedback circuit, but is different from the test circuit 70 according to Embodiment 5 in that the feedback circuit has a configuration of changing the amplification factor. The same configurations as those in Embodiment 1 to Embodiment 5 may have the same signs, and the description thereof may be omitted.

As illustrated in FIG. 12A, the test circuit 70 according to Embodiment 6 includes a capacitive element C8 having one end electrically coupled to the capacitive element C6 and the other end electrically coupled to the input node NODE_R, a switch SW7 having one end electrically coupled between the other end of the capacitive element C6 and one end of the capacitive element C8 and the other end electrically coupled to the input node NODE_R, a capacitive element C9 having one end electrically coupled to the input node NODE_R via the switch SW8 and the other end electrically coupled to a fixed potential VREF5, and a switch SW9 having one end electrically coupled to the input node NODE_R and the other end electrically coupled to the capacitive element C7. In Embodiment 6, the capacitive element C8 is an example of a sixth capacitive element, the capacitive element C9 is an example of a seventh capacitive element, the switch SW7 is an example of a fifth switch, and the fixed potential VREF5 is an example of a fifth potential.

The test circuit 70 of Embodiment 6 illustrated in FIG. 12A may be modified as illustrated in FIG. 12B. The test circuit 70 according to the modification of Embodiment 6 in FIG. 12B has a capacitive element C10 having one end electrically coupled to the output node TEST_OUT of the amplifier 53 and the other end electrically coupled to the input node NODE_R via a switch SW10.

When the test circuit 70 according to Embodiment 6 is operated, the switches SW7, SW8, and SW9 are turned on or off to set the amplification factor of the amplifier 53. In the timing chart illustrated in FIG. 13A, all of the switches SW7, SW8, and SW9 are turned on. In the timing chart illustrated in FIG. 13B, the switch SW7 and the switch SW9 are turned on, and the switch SW8 is turned off. In the timing chart illustrated in FIG. 13C, the switch SW7 is turned off, and the switches SW8 and SW9 are turned on.

As is clear from the amplitudes of the signal of the output node TEST_OUT illustrated in FIGS. 13A, 13B, and 13C, the amplification factor of the amplifier 53 is the largest in the example of FIG. 13B, and the amplification factor decreases in the order of FIGS. 13A and 13C.

As described above, according to the test circuit 70 of Embodiment 6, the following effects can be further obtained in addition to the effects of the test circuits 70 of Embodiment 1 to Embodiment 5.

The test circuit 70 of Embodiment 6 further includes the capacitive element C8 as the sixth capacitive element having one end electrically coupled to the capacitive element C6 as the fourth capacitive element and the other end electrically coupled to the input node NODE_R, the switch SW7 as the fifth switch having one end electrically coupled between the other end of the capacitive element C6 and one end of the capacitive element C8 and the other end electrically coupled to the input node NODE_R, and the capacitive element C9 as the seventh capacitive element having one end electrically coupled to the input node NODE_R and the other end to which the fixed potential VREF5 as the fifth potential is applied.

As described above, according to the test circuit 70 of Embodiment 6, the potential difference between the input node NODE_V and the input node NODE_R is amplified and output according to the capacitances of the capacitive element C6 to the capacitive element C9. Therefore, it is possible to adjust the voltage of the reference potential VREF1 to a predetermined voltage as it should be. Thus, it is possible to implement the test circuit 70 with high accuracy.

### 7. Embodiment 7

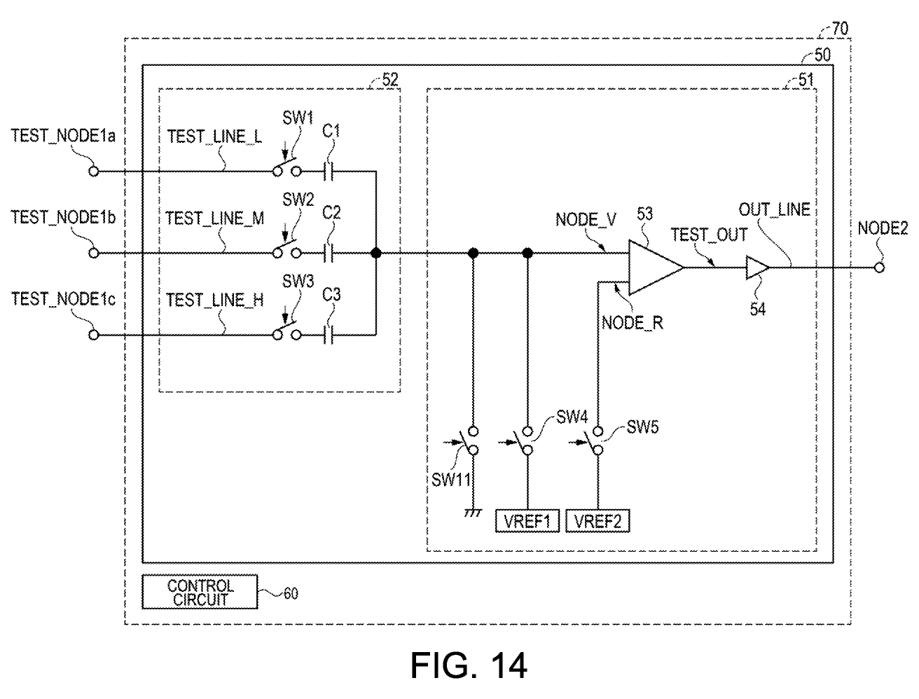

Next, a test circuit 70 according to Embodiment 7 will be described with reference to FIG. 14. FIG. 14 is a circuit diagram of the test circuit 70 according to Embodiment 7.

The test circuit 70 according to Embodiment 7 is different from the test circuits 70 according to Embodiment 1 to Embodiment 6 in that a discharge circuit is provided. The same configurations as those in Embodiment 1 to Embodiment 6 may have the same signs, and the description thereof may be omitted.

The discharge circuit includes a switch SW11 having one end electrically coupled to the input node NODE_V of the amplifier 53 and the other end electrically coupled to a common potential. In the present embodiment, the switch SW11 is an example of a sixth switch, and the common potential is an example of a ground potential.

In the test circuit 70 according to Embodiment 7, the switch SW11 is controlled to be turned on before at least one of the switches SW1, SW2, and SW3 is turned on, and discharges the input node NODE_V of the amplifier 53 to the common potential. As a result, it is possible to prevent an overvoltage exceeding the withstand voltage range of the first circuit 51 from being applied to the first circuit 51 having the low withstand voltage, and to suppress the occurrence of a failure in the first circuit 51.

As described above, according to the test circuit 70 of Embodiment 7, the following effects can be further obtained in addition to the effects of the test circuits 70 of Embodiment 1 to Embodiment 6.

The test circuit 70 of Embodiment 7 further has the switch SW11 as the sixth switch having one end electrically coupled to the input node NODE_V and the other end electrically coupled to the ground potential.

Therefore, according to the test circuit 70 of Embodiment 7, since the input node NODE_V of the amplifier 53 can be discharged to the ground potential, it is possible to implement the test circuit 70 with high reliability.

Although the preferred embodiments are described hereinabove, the present disclosure is not limited to the embodiments described above. In addition, the configuration of each unit according to the present disclosure can be replaced with any configuration that exhibits the same function as that of the above-described embodiments, and any configuration can be added.

What is claimed is:

1. A test circuit comprising:
a first circuit including an amplifier having a first input node, a second input node, and an output node, a first switch having one end electrically coupled to the first input node and another end to which a first potential is applied, and a second switch having one end electrically coupled to the second input node and another end to which a second potential is applied;
a second circuit including a first capacitive element provided between a test node and the first input node and having one end electrically coupled to the first input node, a third switch having one end electrically coupled to another end of the first capacitive element and another end electrically coupled to the test node, a second capacitive element having one end electrically coupled to the first input node, and a fourth switch having one end electrically coupled to another end of the second capacitive element and another end electrically coupled to the test node; and
a control circuit controlling the first circuit and the second circuit, wherein
a withstand voltage of the amplifier is lower than a voltage applied to the test node, and
a capacitance of the second capacitive element is smaller than a capacitance of the first capacitive element.

2. The test circuit according to claim 1, wherein
the control circuit controls a conduction state between the third switch and the fourth switch according to the voltage applied to the test node.

3. The test circuit according to claim 1, wherein
the second potential is a ground potential.

4. The test circuit according to claim 1, wherein
the test node has a first test node and a second test node,
the first test node is electrically coupled to the other end of the third switch, and
the second test node is electrically coupled to the other end of the fourth switch.

5. The test circuit according to claim 1, further comprising a third capacitive element having one end electrically coupled to the first input node and another end to which a third potential is applied.

6. The test circuit according to claim 1, wherein
the other end of the first switch and the other end of the second switch are electrically coupled to a same power supply.

7. The test circuit according to claim 1, further comprising:
a fourth capacitive element having one end electrically coupled to the output node and another end electrically coupled to the second input node; and
a fifth capacitive element having one end electrically coupled to the second input node and another end to which a fourth potential is applied.

8. The test circuit according to claim 7, further comprising:
a sixth capacitive element having one end electrically coupled to the fourth capacitive element and another end electrically coupled to the second input node,
a fifth switch having one end electrically coupled between the other end of the fourth capacitive element and the one end of the sixth capacitive element and another end electrically coupled to the second input node; and
a seventh capacitive element having one end electrically coupled to the second input node and another end to which a fifth potential is applied.

9. The test circuit according to claim 1, further comprising a sixth switch having one end electrically coupled to the first input node and another end electrically coupled to a ground potential.

10. An electro-optical device comprising:
an electro-optical panel;
a drive circuit that drives the electro-optical panel; and
the test circuit according to claim 1.

11. The electro-optical device according to claim 10, wherein when the electro-optical panel is driven by the drive circuit, the second switch is turned off.
